(19) United States
(12) Patent Application Publication
(10) Pub. No.: US 2003/0042587 A1
(43) Pub. Date: Mar. 6, 2003

(54) IC packaging and manufacturing methods

(76) Inventor: Tsung-Jen Lee, San-Chung City (TW)

Correspondence Address: BIRCH STEWART KOLASCH & BIRCH, PO BOX 747, FALLS CHURCH, VA, 22040-0747, US

(21) Appl. No.: 10/230,334

(22) Filed: Aug. 29, 2002

(30) Foreign Application Priority Data
Aug. 31, 2001 (TW) 90121706

(51) Int. Cl. H01L 23/02; H01L 23/34; H01L 23/48; H01L 23/52; H01L 29/40

(52) U.S. Cl. 257/678; 257/778; 257/737; 257/738; 257/723; 257/685; 257/686

(57) ABSTRACT

The present invention provides a new IC packaging and its manufacturing methods. This technology simultaneously combines Flip Chip (FC), Ball Grid Array (BGA), and Chip on Chip (COC) packages to form a vertically stacked IC such that multiple semiconductor chips can be integrated into a single, small factor IC product. Each semiconductor chip as well as the substrate of the final IC product can be manufactured, tested, and assembled separately under its own optimal manufacturing conditions, thereby increasing yield, lowering manufacturing cost, and shortening processing time. Another advantage of this new technology is that the length of the interconnects between the semiconductor chips as well as between each semiconductor chip and the substrate is shorter than those of known IC packages. The reduction of the length of the rerouting lines enhances electrical performance because inductance of the signal path is greatly reduced. Furthermore, using this technology, new product specifications can be achieved in a relatively short time by merely rearranging the semiconductor chips to change or extend functions.

### BACKGROUND OF INVENTION

1. Field of the Invention

This invention relates generally to a new technology in IC packaging and its manufacturing methods for vertically integrating several semiconductor chips of various functions on a single substrate to construct a highly integrated, small factor IC product.

2. Related Art

Current technological developments in high-density integration of semiconductor chips rely heavily on advanced and sophisticated photolithography processes. Some technologies have been developed to integrate logical and memory circuits into one IC product as with various System On Chip designs. The emergence of these technologies has initiated the demand for large-scale circuit integration.

The main bottleneck in manufacturing this type of new products is that circuits with different functions and/or characteristics, such as logic, memory, power supply, and high frequency circuits, have to be placed together on the same chip. In other words, various circuits need to be mounted on the same silicon substrate. The problem with this process is that the most suitable manufacturing process for memory circuits may not be the most suitable for logical circuits. Also, the most suitable manufacturing conditions for an Application Specific IC (ASIC) may not be suitable for manufacturing memory circuits.

Moreover, testing methods differ depending on the type of circuit. For example, the testing method for a logical circuit is different from that for a memory circuit. Hence, it is necessary for a manufacturer to develop a testing method that is suitable for both. Another problem that System On Chip faces is that the end product is considered defective when only one of the many circuits is defective. In other words, although this technology can integrate circuits of various functions on a single chip, the difficulty is extremely high and the product yield is quite low, which translates into a higher production cost.

Related Art as shown in FIG. 33 addresses the problems above. This technology places chip C1 on substrate C3 and at the same time chip C2 is attached to chip C1 using die bonding paste. Chip C1 and chip C2 are then connected to substrate C3 separately using wire bonds C5 and C6, respectively. Finally, epoxy-molding C7 is employed to package these components into a single product. This package can then be connected to external devices or circuits using solder balls on the bottom side of substrate C3. Although this technology adopts the traditional wire-bonding method to connect the chips to the substrate, there are still several challenges to overcome. These are as follows:

1. The use of wire bonding requires peripheral substrate room for bonding pads on chips C1 and C2, and therefore the size of the chips and substrate cannot be reduced.

2. Wires C5 and C6 must exceed the height of chips C1 and C2 for wire bonding to take place because the electrical connections are on top of the chips. However, the longer the wires C5 and C6 are, the worse the electrical performance is. This becomes increasingly important with increased frequency.

3. The die bonding paste forms a layer between chips C1 and C2 with mechanical strength that can neither be too strong nor too weak. If the mechanical strength is too strong, the structure may be damaged during wire bonding. On the other hand, if the mechanical strength is too weak, there will be insufficient contact. In order to maintain a certain mechanical strength during wire bonding, the rigidity of substrate C3 must be increased. As a result, the thickness of substrate C3 must be increased, and hence the total package size increases.

### SUMMARY OF INVENTION

The primary objective of this invention is to first allow each chip to be produced separately using its optimal manufacturing process and then assembled into an IC package with minimal interconnect length between the chips and the substrate so that electrical performance can be enhanced. As a result, a small factor IC package can be easily produced at a low cost.

Based on this invention, chips produced using various manufacturing processes can first be stacked using Chip On Chip (COC). This stack of chips, along with other chips, can then be attached to a substrate using Flip Chip (FC) technology. The substrate has a surface with Ball Grid Array (BGA), which provides the points for external electrical interconnection.

According to this invention, semiconductor chips can be attached to both sides of the aforementioned substrate and then electrically connected to another substrate with BGA on the surface to make external electrical interconnection points. Furthermore, the aforementioned substrate can be locally excavated to house the smaller of a stacked set of chips and allow the top surface of the substrate surrounding the hollow to be electrically connected to the bigger chip using Flip Chip.

According to this invention, an interposer between the aforementioned substrates can be used to make electrical interconnection. Using the through holes in the interposer or wires, semiconductor devices produced based on this invention can be integrated into a single IC package to extend its specifications or functions.

IC packages produced based on this invention can also be integrated with an optoelectronic device through the use of caps. Also, with a CPU or logic device used as the main semiconductor chip of the IC, while flash memory, SRAM, or DRAM, used as the other semiconductor chips, an IC package similar to that of a Single Chip Micro-computer can be produced at a low cost.

Since the length of interconnects among the control, logic, and memory devices is quite short, the electromagnetic interference (EMI) can be reduced such that functional stability of the electrical signals between the chips is sustained.

To have a clearer understanding of the objectives, characteristics, and advantages of this invention, detailed descriptions of various concrete examples along with the corresponding FIGS are given below.

### BRIEF DESCRIPTION OF THE DRAWINGS

The preferred embodiment of the multifunctional cooking apparatus according to the present invention is illustrated in the accompanying drawings, wherein:

FIG. 1: An isometric view of the IC package for Embodiment I.

FIG. 2: A bottom view of the semiconductor chip in Embodiment I with the connecting point distribution shown.

FIG. 3: A cross-sectional view of one part of the IC package for Embodiment I.

FIG. 4: A cross-sectional view of another part of the IC package for Embodiment I.

FIG. 5: A cross-sectional view of another part of the IC package for Embodiment I.

FIG. 6: A cross-sectional view of the IC package for Embodiment II.

FIG. 7: A cross-sectional view of the IC package for Embodiment III.

FIG. 8: A cross-sectional view of the other IC package for Embodiment III.

FIG. 9: A cross-sectional view of the IC package for Embodiment IV.

FIG. 10: A cross-sectional view of the IC package for Embodiment V.

FIG. 11: A cross-sectional view of another variant IC package for Embodiment V.

FIG. 12: A cross-sectional view of another variant IC package for Embodiment V.

FIG. 13: A cross-sectional view of the IC package for Embodiment VI.

FIG. 14: A cross-sectional view of another variant IC package for Embodiment VI.

FIG. 15: A cross-sectional view of another variant IC package for Embodiment VI.

FIG. 16: A cross-sectional view of another variant IC package for Embodiment VI.

FIG. 17: A cross-sectional view of another variant IC package for Embodiment VI.

FIG. 18: A cross-sectional view of another variant IC package for Embodiment VI.

FIG. 19: A cross-sectional view of another variant IC package for Embodiment VI.

FIG. 20: A cross-sectional view of another variant IC package for Embodiment VI.

FIG. 21: A cross-sectional view of another variant IC package for Embodiment VI.

FIG. 22: A cross-sectional view of the IC package for Embodiment VII.

FIG. 23: A cross-sectional view of another variant IC package for Embodiment VII.

FIG. 24: A cross-sectional view of the other IC package for Embodiment VII.

FIG. 25: A cross-sectional view of another variant IC package for Embodiment VII.

FIG. 26: A flow chart of the manufacturing process used to produce the IC package in Embodiment VIII.

FIG. 27: A flow chart of the manufacturing process used to produce the IC package in Embodiment IX.

FIG. 28: A flow chart of the manufacturing process used to produce the IC package in Embodiment X.

FIG. 29: A flow chart of the manufacturing process used to produce the IC package in Embodiment XI.

FIG. 30: A flow chart of the manufacturing process used to produce the IC package in Embodiment XII.

FIG. 31: A flow chart of the manufacturing process used to produce the IC package in Embodiment XIII.

FIG. 32: A flow chart of the manufacturing process used to produce the IC package in Embodiment XIV.

FIG. 33: The prior art of an IC package.

### DETAILED DESCRIPTION OF PREFERRED EMBODIMENT

[Package Structure, Embodiment I]

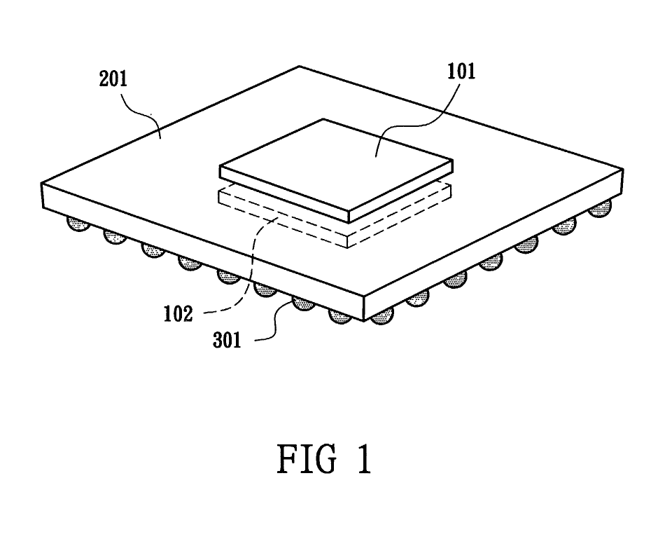

A three-dimensional view of the IC package based on this invention is shown in FIG. 1. After semiconductor chips 101 and 102 have separately been manufactured and tested, they are electrically connected to each other using Chip On Chip (COC) method, or individually to substrate 201 using flip-chip bonding to form an IC package. This IC package has BGA interconnects on substrate 201 to make external electrical connection.

In each of the examples related to this invention, chips 101 and 102 can be any one of the following: a control device, logic device, memory device, charge-coupled device, or voltage regulator. Control devices can be a Central Processing Unit (CPU), Micro Processor Unit (MPU), or Digital Signal Processor (DSP); and logic devices can be a Logic Integrated Circuit. Memory devices can be a Static Random Access Memory (SRAM), Dynamic Random Access Memory (DRAM), Erasable Programmable Read-only Memory (EPROM), or any other type of flash memory.

Moreover, in the following examples, the charge-coupled device that constitutes semiconductor chips 101 and 102 can be a device that takes advantage of the movement of an electric charge to transmit information; an example of which can be a Charge Coupled Device (CCD). At the same time, either chip 101 or 102 can be a voltage regulator, which can convert an external power supply to provide electricity for the other chips; an example of which can be a DC 5V˜3V transformer.

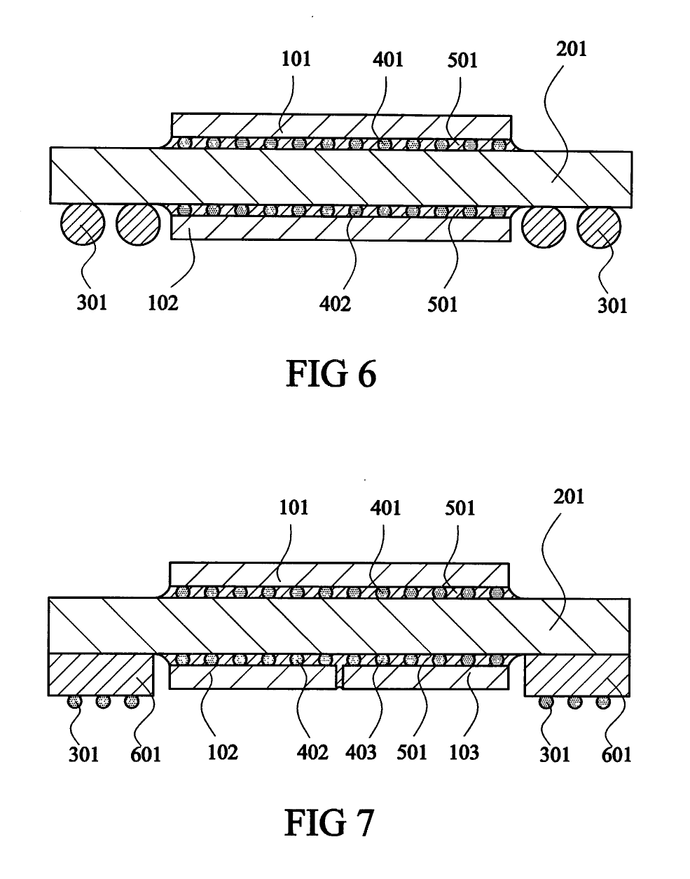

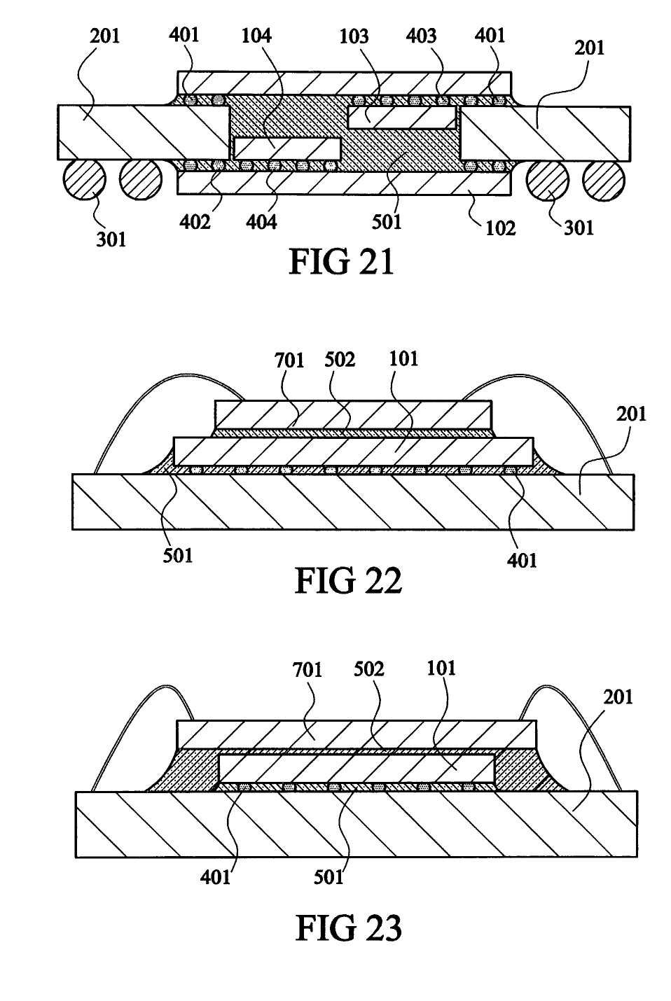

Substrate 201 in the examples can be of an insulating material. These can include substrates such as Aramid organic substrate, ceramic substrate, Polyamide substrate, or epoxy substrate. On one side of substrate 201, there may be some area array-type external connection terminals 301 (this part is not shown in FIG. 1, but readers can refer to the illustrations in FIGS. 6 to 25). These external connection terminals 301 can be solder balls or terminals that electrically connect to the conducting pattern layer of substrate 201. The electrical connection between semiconductor chips 101 and 102 is achieved through the multiple conducting pattern layers of substrate 201. However, the electrical connection between semiconductor chips 101 and 102 can also be achieved by Chip On Chip (COC) technology.

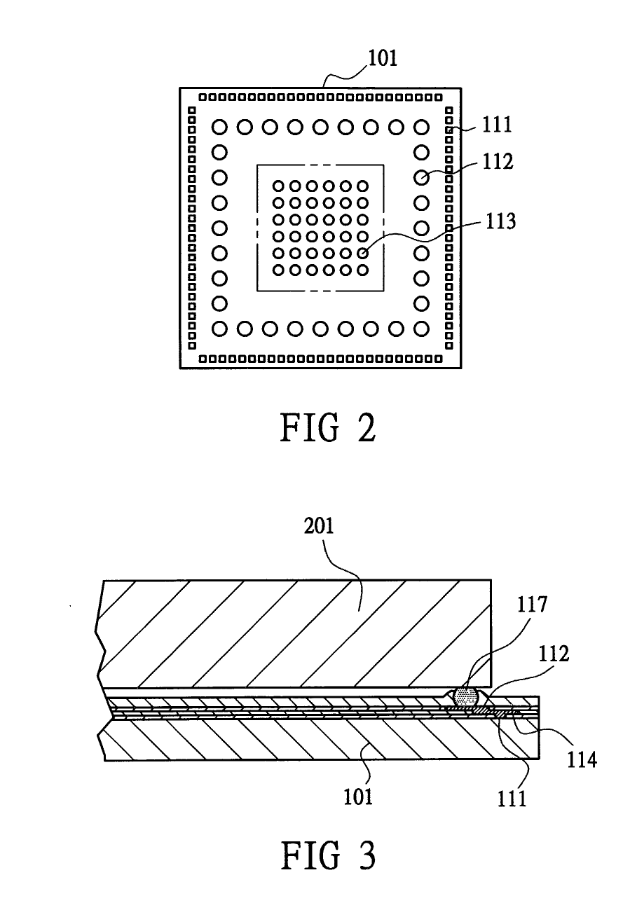

Referring to FIG. 2, semiconductor chip 101 has three types of terminals—111, 112, and 113 for different purposes. The outer terminal 111 provides connection points for wire bonding, terminal 112 provides connection points for connecting to substrate 201 using flip-chip bonding, and terminal 113 in the center provides the connection points for connecting to semiconductor chip 102 using COC method.

FIG. 3 illustrates how semiconductor chip 101 is connected to substrate 201. Terminal 111 is connected to terminal 112 through conductive wire 114, and at the same time, it can also be electrically connected to substrate 201 through the use of conductive material 117 (such as area array-type distributed solder bumps or solder balls).

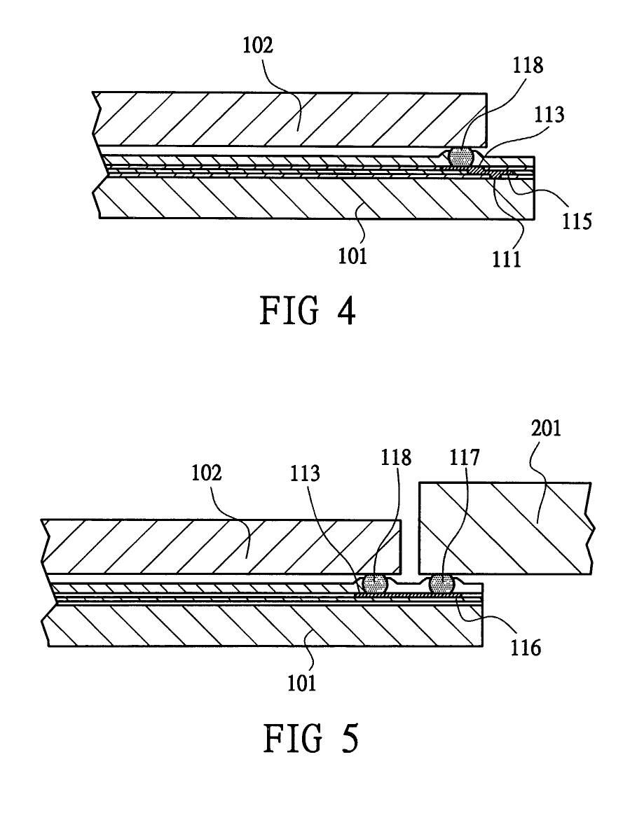

FIG. 4 illustrates how chip 101 is connected to chip 102. Terminal 111 is connected to terminal 113 through conductive wire 115 (conductive pattern layer and through-hole), and at the same time, it can also be electrically connected to chip 102 through the use conductive material 118 (such as area array-type distributed solder bumps or solder balls). As a result, semiconductor chip 101 goes through terminal 111 to conductive wire 115 to terminal 113 to conductive material 118 and electrically connects to chip 102.

For the method of connection between semiconductor chips 101 and 102 and substrate 201, please refer to FIG. 5. Terminal 112 is connected to terminal 113 through conductive wire 116 (such as printed wires and through-holes for PWB), and at the same time, it can also be connected to chip 102 and substrate 201 through the use of conductive materials 117 and 118 (such as solder balls). As a result, semiconductor chip 102 goes through conductive material 118, terminal 113, conductive wire 116, terminal 112, conductive material 117, and then electrically connects to substrate 201.

Using the IC package and packaging methods of this invention, the size of an IC package can be reduced, or more semiconductor devices can be packaged in the same amount of space. Under optimal manufacturing process and testing conditions, these devices can be manufactured separately by companies of different specialization and then assembled together using the technology presented by this invention to minimize the total package size.

[Package Structure, Embodiment II]

FIG. 6 presents another IC package that uses a packaging method based on this invention. The IC package includes at least the following: semiconductor chip 101, semiconductor chip 102, substrate 201, multiple array-type distributed external connection terminals 301, multiple internal connection terminals 401, 402, and underfill encapsulant 501. Substrate 201 connects to semiconductor chips 101 and 102 through the use of internal connection terminals 401 and 402, respectively.

In this example, the connection between semiconductor chips 101, 102 and substrate 201 is made separately using flip-chip bonding. And, the electrical connection between semiconductor chips 101, 102 and external connection terminal 301 is made through the printed wires and through-holes on substrate 201. Underfill encapsulant 501 is an insulator such as epoxy-resin which fills the. For example, using epoxy-resin fills the gaps between semiconductor chips 101, 102 and substrate 201 in order to increase the strength of adhesion, to mitigate stress concentration on terminals 401 and 402 caused by temperature variation, metal fatigue, delamination, or open contact.

In the examples, semiconductor chips 101 and 102 can be a memory device and a control device, respectively. For example, one of the semiconductor chips can be a Central Processing Unit (CPU) or a logic device and the other chip can be a flash memory, SRAM, or DRAM. Using this combination, an IC package such as a Single Chip Micro-computer can be produced at low cost. Using this kind of structure, the wire between the control device or logic device and the memory device is very short such that electromagnetic interference can be reduced.

To increase memory capacity, semiconductor chips 101 and 102 as shown in FIG. 6 can both be flash memory, SRAM, or DRAM. As a result, the IC package based on this invention can double the memory capacity without doubling the size of the package.

Furthermore, one of the semiconductor chips 101 and 102 can be a DC-DC converter (e.g. converting 5V external voltage into 3V supply voltage) and the other a 3V flash memory. As a result, the voltage of external power supply can be reduced for the use of flash memory.

[Package Structure, Embodiment III]

FIG. 7 presents another IC package that uses the packaging method of this invention. The IC package includes at least the following: semiconductor chip 101, semiconductor chip 102, semiconductor chip 103, substrate 201, external connection terminal 301, internal connection terminal 401, internal connection terminal 402, internal connection terminal 403, underfill encapsulant 501, and interposer 601.

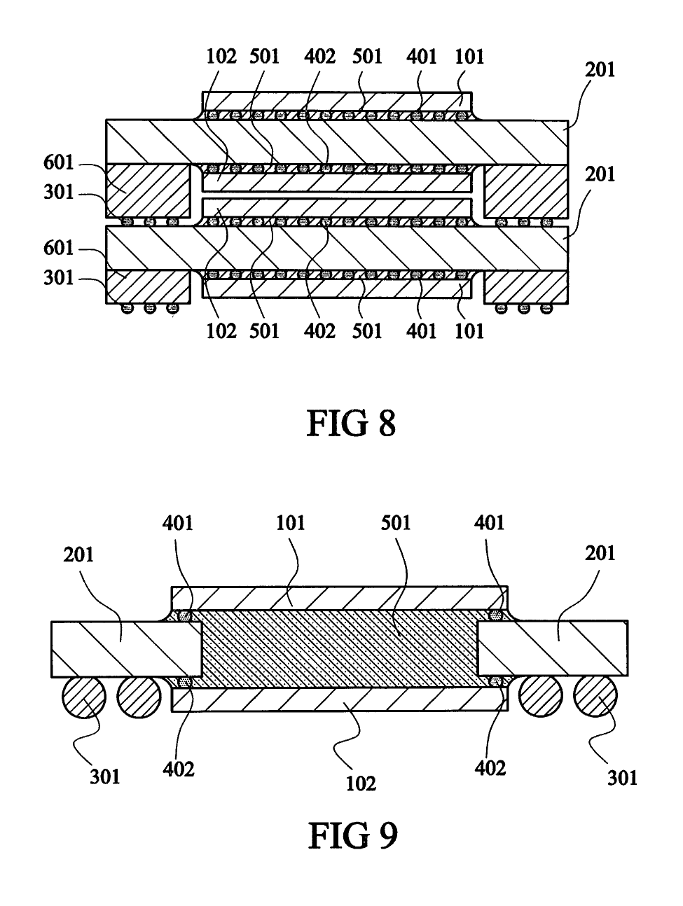

In this example, one side of substrate 201 is connected to semiconductor chip 101 through internal connection terminal 401, while the other side to semiconductor chips 102 and 103 through internal connection terminals 402 and 403, respectively. As shown in FIG. 7, interposer 601 and substrate 201 are electrically connected. The purpose of this interposer is to prevent semiconductor chips 102 and 103 from coming into contact with other substrates or components when vertical stacking is performed (please refer to FIG. 8). Some through-holes are made on interposer 601 so that semiconductor chips 101, 102, and 103 can be electrically connected to area-array distributed terminals 301 on interposer 601, via the printed wires and through-holes fabricated on substrate 201.

In practical application, semiconductor chips 101, 102, and 103 can be a memory or control device. For example, one of the semiconductor chips can be a Central Processing Unit (CPU) or a logic device and the other two chips can be flash memory, SRAM, or DRAM. Using this type of structure, an IC package such as a Single Chip Micro-computer can be produced at low cost. With this structure, the wire between the control device or logic device and the memory device is very short, and therefore the electromagnetic interference can be reduced.

To increase memory capacity, semiconductor chips 101, 102 and 103 can be a combination of flash memory, SRAM, or DRAM. Using this kind of a structure, the memory capacity of the IC package can be tripled without tripling the size of the package. In order to obtain a suitable supply voltage, one of the semiconductor chips 101, 102, or 103 can be a DC-DC converter (e.g. converting 5V external voltage into 3V working voltage) and the others 3V flash memory. As a result, the voltage of the external power supply can be lowered for the use of flash memory.

With interposer 601, the structure allows repeated vertical stacking. As the IC package in FIG. 8 shows, interposer 601 separates and electrically connects two consecutive units in a way that does not allow the mounted devices to touch each other. As illustrated in FIG. 8, the components of this structure include semiconductor chips 101 and 102, substrate 201, external connection terminals 301, internal connection terminals 401 and 402, underfill encapsulant 501, and interposer 601.

[Package Structure, Embodiment IV]

The major difference between the IC package shown in FIG. 9 and the previous examples is that there is an opening on substrate 201. The gap between semiconductor chips 101 and 102 and the opening are filled with underfill encapsulant 501.

[Package Structure, Embodiment V]

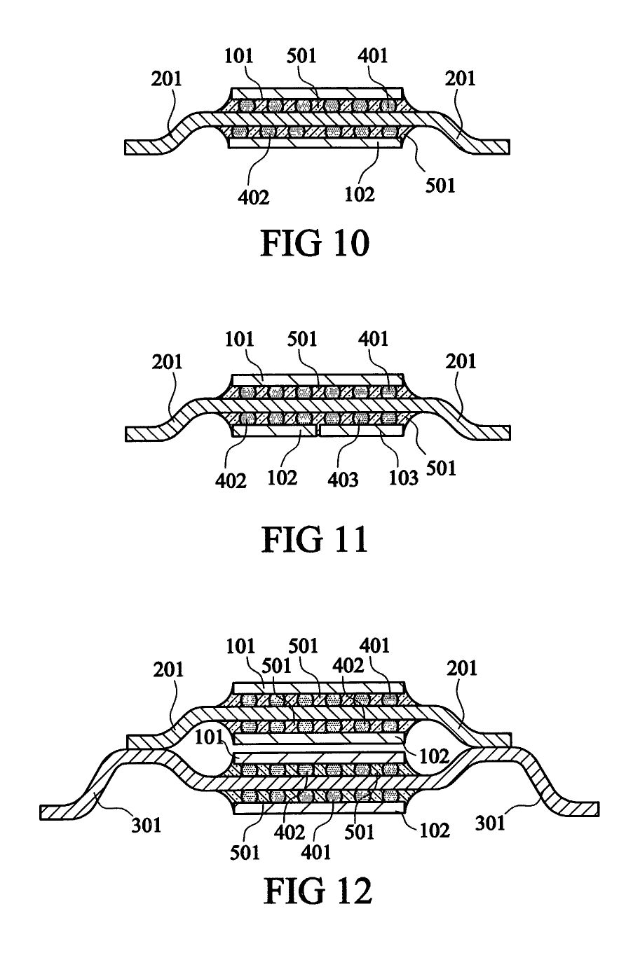

The major difference between the IC packages shown in FIGS. 10, 11, and 12 and the previous examples is that substrate 201 is a flexible substrate such as polyimide tape with printed wire and terminals. The IC package in this example includes semiconductor chips 101, 102, and 103, substrate 201, external connection terminal 301, internal connection terminals 401 and 402, and underfill encapsulant 501.

The advantage of the IC packages in this example is that the shape of substrate 201 can be changed by bending it, thereby eliminating the need for an interposer. When multiple packages are vertically stacked as shown in FIG. 12, the structure maintains the function of separation to prevent any two consecutive units from touching each other.

[Package Structure, Embodiment VI]

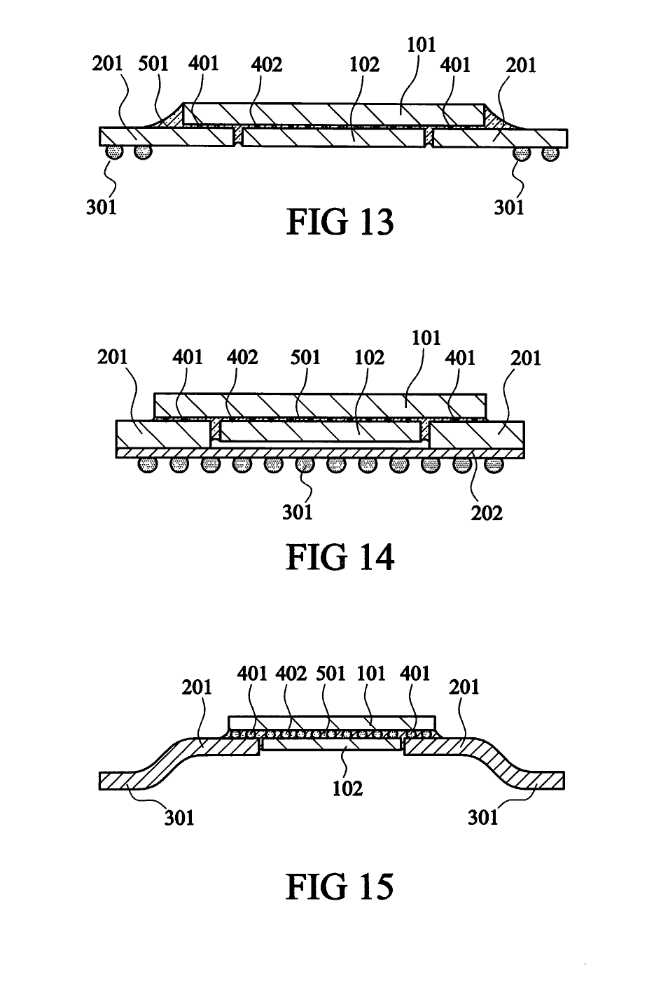

The major characteristic of the IC packages shown in FIGS. 13 to 21 is that substrate 201 has an opening to house semiconductor chip 102. This opening can be a through-hole or milled cavity at the base of substrate 201.

As shown in FIG. 13, the IC package includes semiconductor chips 101 and 102, substrate 201, external connection terminal 301, internal connection terminals 401 and 402, and underfill encapsulant 501. Semiconductor chips 101 and 102 are connected by means of internal connection terminal 402 using Chip On Chip (COC) technology. Through internal connection terminal 401, semiconductor chip 101 is then connected to substrate 201 using flip-chip bonding (FCB). By external connection terminal 301 on substrate 201, semiconductor chip 101 can be electrically connected to peripherals or circuits outside of the package by using BGA technology. According to the aforementioned structure, semiconductor chips 101 and 102 can be electrically connected to each other without using the printed circuits on substrate 201. Therefore, less printed wires are required for signal interconnection, and hence, the production of substrate 201 becomes easier and less expensive, and the size of the whole IC package can also be reduced.

FIG. 14 shows an IC package based on this invention that includes semiconductor chips 101 and 102, substrates 201 and 202, external connection terminal 301, internal connection terminals 401 and 402, and underfill encapsulant 501. The gap between semiconductor chips 101 and 102 and substrate 201 is filled with underfill encapsulant 501. Then, semiconductor chip 102, which is protected by the opening of substrate 202 can, through external connection terminal 301, form a BGA-type electrical connection with peripherals or circuits outside the package such that the degree of freedom for designing the terminal can be increased.

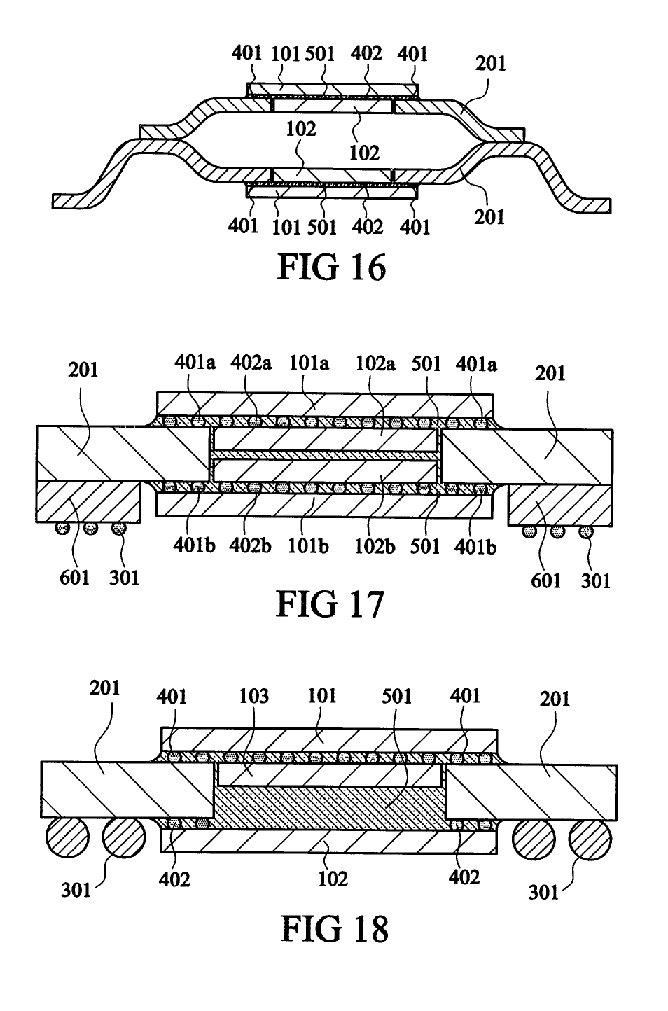

Referring to FIG. 15, substrate 201 of the IC package can be replaced by a flexible substrate such that substrate 201 can be bent and thereby eliminating the need for the interposer used in the previous example. As a result, multiple IC packages can be vertically stacked as shown in FIG. 16.

Referring to FIG. 17, if substrate 201 is a regular substrate, then interposer 601 can be used to avoid a lack of space for components when multiple IC packages are vertically stacked. The IC package shown in the figure includes semiconductor chips 101a, 101b, 102a, and 102b, substrate 201, interposer 601, external connection terminal 301, internal connection terminals 401a, 401b, 402a, and 402b and underfill encapsulant 501. Since there is a cavity in substrate 201 to house semiconductor chips 102a and 102b, when there is a need to enlarge the vertical gap for the chips, all that is necessary is to increase the height of interposer 601. Therefore, the height of semiconductor chip 101b need not be reduced. to form an IC package. Since the connection among all the components is the same as the previous example, its description will not be repeated here.

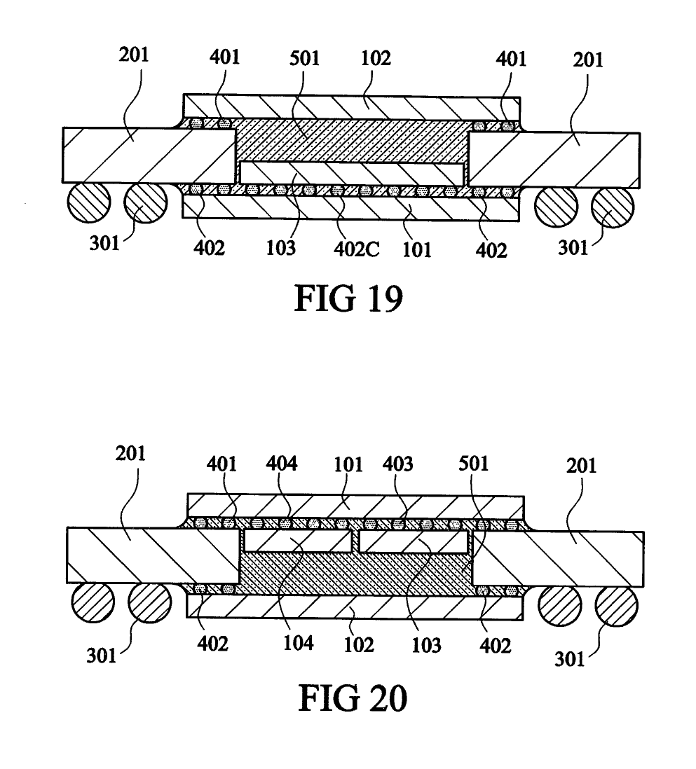

As shown in FIG. 18, the IC package can only include semiconductor chips 101, 102, and 103, substrate 201, external connection terminal 301, internal connection terminals 401, 402, and 403, and underfill encapsulant 501. Furthermore, the structures of the IC packages shown in FIGS. 19 and 20 are similar to the structure in FIG. 18, except that the number of semiconductor chips and their location are slightly different. Since the choice of components and connection among all the components are the same as the previous example, their descriptions will not be repeated here.

[Package Structure, Embodiment VII]

The IC package of this invention can also use a cap (cap 901) in conjunction with an optoelectronic device. As shown in FIGS. 22 and 23, the IC package includes substrate 201, semiconductor chip 101, and optoelectronic device 701. Substrate 201 and chip 101 are connected using flip-chip bonding, and then underfill encapsulant 501 is used beneath the chip to enhance the strength of the structure. Optoelectronic device 701 can be a sensor, Charge Coupled Device (CCD), or any other optoelectronic device. Optoelectronic device 701 is mounted on top of semiconductor chip 101 with Chip Coating Paste 502, an insulating material. Substrate 201 can be a Tape Automated Bonding (TAB) substrate and use wire bonding to make electrical connection with optoelectronic device 701. Hence, optoelectronic device 701 can electrically connect to semiconductor chip 101 through the printed wires on substrate 201.

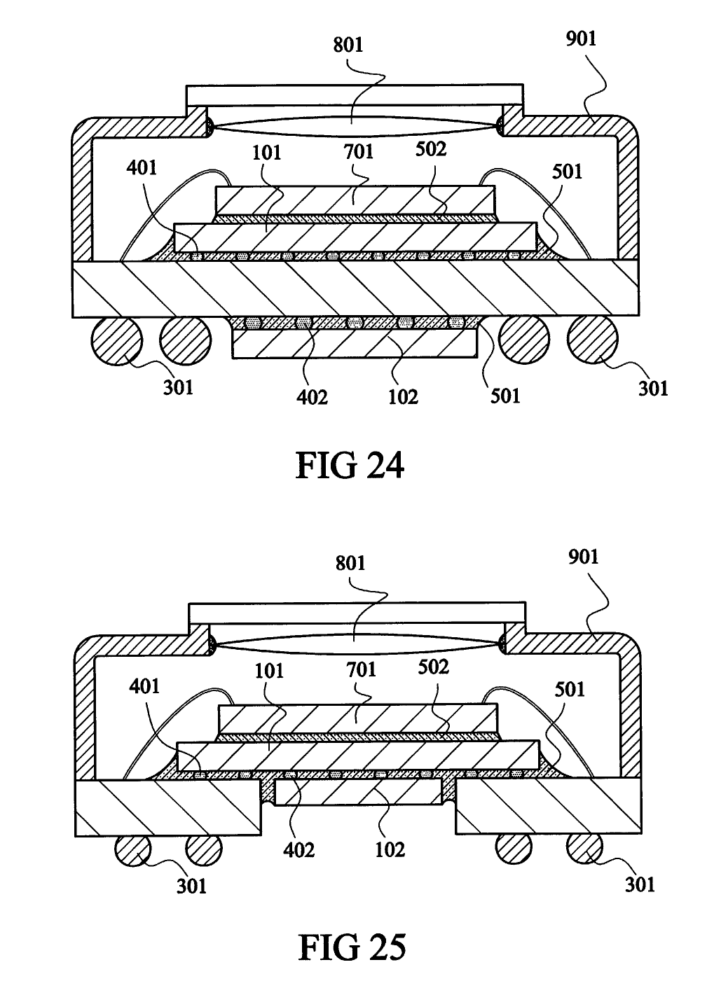

As shown in FIG. 24, the IC package can have lens 801 and cap 901 added to the top of optoelectronic device 701. Lens 801 is fixed onto substrate 201 using cap 901 and maintains a certain distance from optoelectronic device 701 (CCD). Hence, lens 801 can be the light collector of the optoelectronic device 701 (CCD) and cap 901 can be used to prevent dust from falling to the surface of optoelectronic device 701. In other words, the components of the IC package include semiconductor chips 101 and 102, substrate 201, external connection terminal 301, internal connection terminals 401 and 402, underfill encapsulant 501, optoelectronic device 701, lens 801, and cap 901. Substrate 201 is connected to semiconductor chip 101 through internal connection terminal 401. Connected to the other side of substrate 201 through internal connection terminal 402 is semiconductor chip 102. These three components can be combined together through flip-chip bonding (FCB). Underfill encapsulant 501 can then be used beneath the chip to increase reliability by reducing the strain on the solder bumps during thermal cycling and also increase the mechanical strength of the chip-underfill-substrate system.

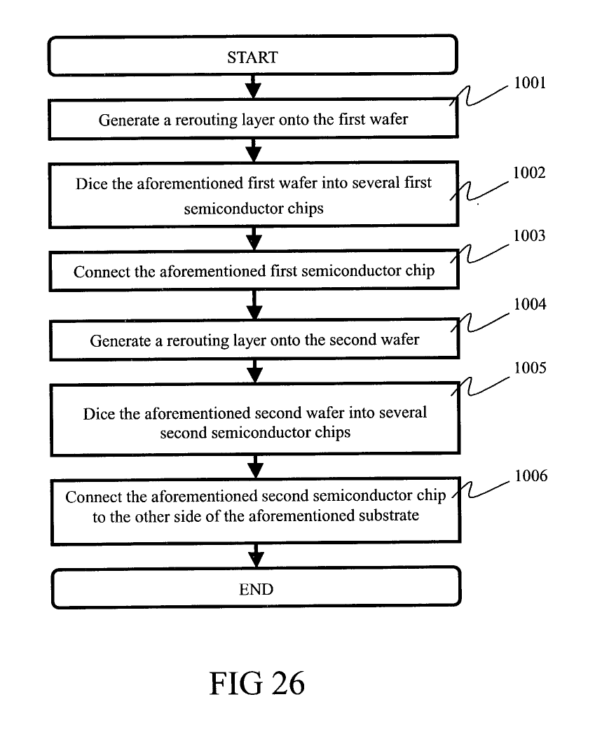

To further reduce the thickness of an IC package, please refer to FIG. 25. The major difference between FIG. 25 and FIG. 24 is that substrate 201 has an opening to house semiconductor chip 102. This opening can be a through-hole or milled cavity on the base of substrate 201. For characteristics and advantages of this opening, please refer to the description of Example 6.

[Manufacturing Method, Embodiment VIII] (Please Refer to FIG. 26 for This Example and FIG. 5 for Related Structure.)

The manufacturing procedure for IC packages of this invention can be as follows:

1. Generate a rerouting layer onto the first wafer (Step 1001) using existing technology. Suppose that this first wafer is for manufacturing CPU chips. The manufacturing of this wafer can be outsourced to a company with a specialty in manufacturing CPUs. This wafer is therefore manufactured under optimal production conditions for CPUs. After the wafer is manufactured, a rerouting layer for connecting to substrate 201 is generated onto it using some existing technology. For example, after generating an insulating film on this wafer, a base metal film such as W or Ni is deposited onto the wafer using vacuum evaporation sputtering method. On this metal film, a specific pattern is formed using photolithography technology, and a layer of Cu or other types of conducting metal is deposited to create a rerouting layer. A polyimide film is then coated, and an opening at location of terminal 112 is formed. Finally, conductor 117 is attached.

2. Dice the aforementioned first wafer into several first semiconductor chips (Step 1002). Some product testing can be conducted before or after dicing the first wafer, if necessary.

3. Connect the aforementioned first semiconductor chip onto a substrate (Step 1003). Semiconductor 101 (CPU) and substrate 201 can be connected using flip-chip bonding.

4. Generate a rerouting layer onto the second wafer (Step 1004) using some existing technology. Suppose that this second wafer is for manufacturing ROM chips. The manufacturing of this wafer can be outsourced to a company with a specialty in manufacturing ROMs. This wafer is therefore manufactured under optimal production conditions for ROMs. After the wafer is manufactured, a rerouting layer for connecting to substrate 201 is generated onto it using some existing technology.

5. Dice the aforementioned second wafer into several second semiconductor chips (Step 1005), which are the semiconductor chip 102 (ROM) mentioned in the previous package structure examples. Some product testing can be conducted before or after dicing the second wafer, if necessary.

6. Connect the aforementioned second semiconductor chip to the other side of the aforementioned substrate (Step 1006). For example, flip-chip bonding can be used to electrically connect semiconductor chip 101 (CPU) and substrate 201.

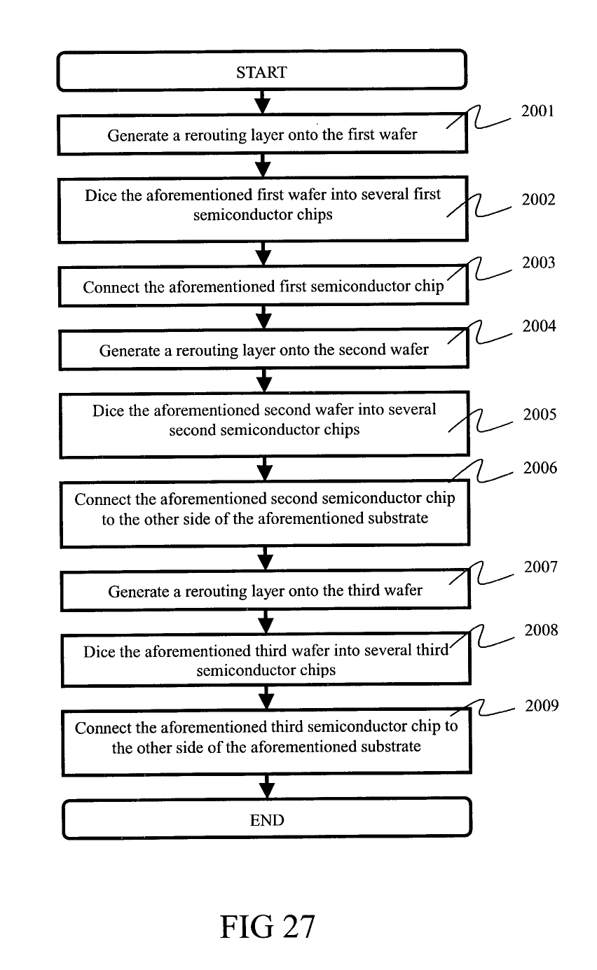

To reduce thermal stresses, strains, and fatigue of the solder joints during thermal cycling, which can cause cracking on the flip-chip bonding joints, underfill encapsulant 501 is used to fill the gap between substrate 201 and semiconductor chips 101 and 102. Using the procedure mentioned above, an IC package like Single Chip Microcomputer of a small size can be produced at relatively low cost.

[Manufacturing Method Embodiment IX] (Please Refer to FIG. 27 for This Example and FIG. 7 for Related Structure.)

The manufacturing procedure for IC packages of this invention can be as follows:

1. Generate a rerouting layer onto the first wafer (Step 2001) using some existing technology.

2. Dice the aforementioned first wafer into several first semiconductor chips (Step 2002).

3. Connect the aforementioned first semiconductor chip onto a substrate (Step 2003).

4. Generate a rerouting layer onto the second wafer (Step 2004) using some existing technology.

5. Dice the aforementioned second wafer into several second semiconductor chips (Step 2005).

6. Connect the aforementioned second semiconductor chip to the other side of the aforementioned substrate (Step 2006).

7. Generate a rerouting layer onto the third wafer (Step 2007) using some existing technology.

8. Dice the aforementioned third wafer into several third semiconductor chips (Step 2008).

9. Connect the aforementioned third semiconductor chip to the other side of the aforementioned substrate (Step 2009).

The manufacturing of the aforementioned wafers can be outsourced to companies of different manufacturing specialties with optimal production conditions for certain chips. After the chips are manufactured, flip-chip bonding can be used to electrically connect the semiconductor chips to substrate 201. To reduce thermal stress concentration due to thermal cycling that may cause cracking on the surface of flip-chip bonding, underfill encapsulant 501 is used to fill the gap between substrate 201 and all the semiconductor chips. Using the procedure mentioned above, an IC package like Single Chip Microcomputer of a smaller form factor can be produced at relatively low cost.

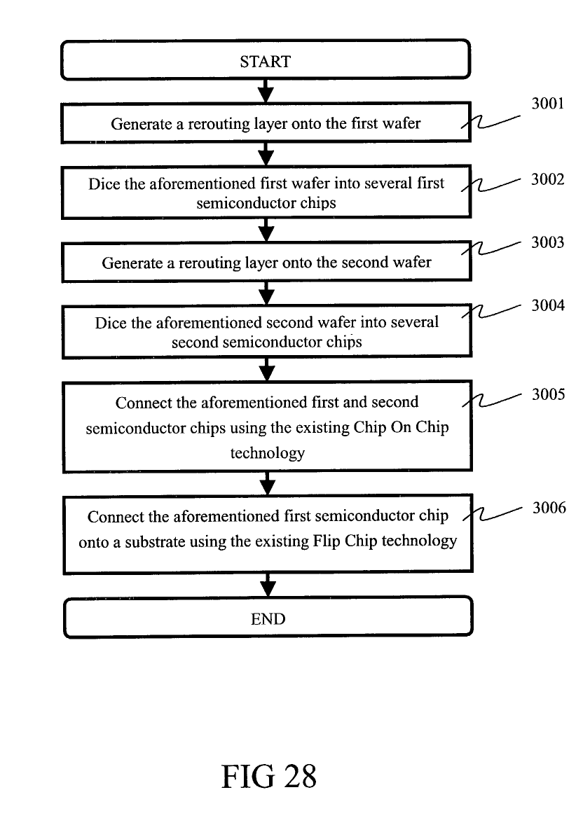

Manufacturing Method Embodiment X (Please Refer to FIG. 28 for This Example and FIG. 13 for Related Structure.)

The manufacturing procedure for this invention is as follows:

1. Generate a rerouting layer onto the first wafer (Step 3001) using some existing technology.

2. Dice the aforementioned first wafer into several first semiconductor chips (Step 3002).

3. Generate a rerouting layer onto the second wafer (Step 3003) using some existing technology.

4. Dice the aforementioned second wafer into several second semiconductor chips (Step 3004).

5. Connect the aforementioned first and second semiconductor chips using the existing Chip On Chip technology (Step 3005).

6. Connect the aforementioned first semiconductor chip onto a substrate using the existing Flip Chip technology (Step 3006).

Similarly, the manufacturing of the aforementioned wafers can be outsourced to companies of different manufacturing specialties with optimal production conditions for certain chips. To reduce thermal stress concentration due to thermal cycling that may cause cracking on the surface of flip-chip bonding, underfill encapsulant 501 is used to fill the gap between substrate 201 and all the semiconductor chips. Using the procedure mentioned above, an IC package like Single Chip Microcomputer of a smaller form factor can be produced at relatively low cost.

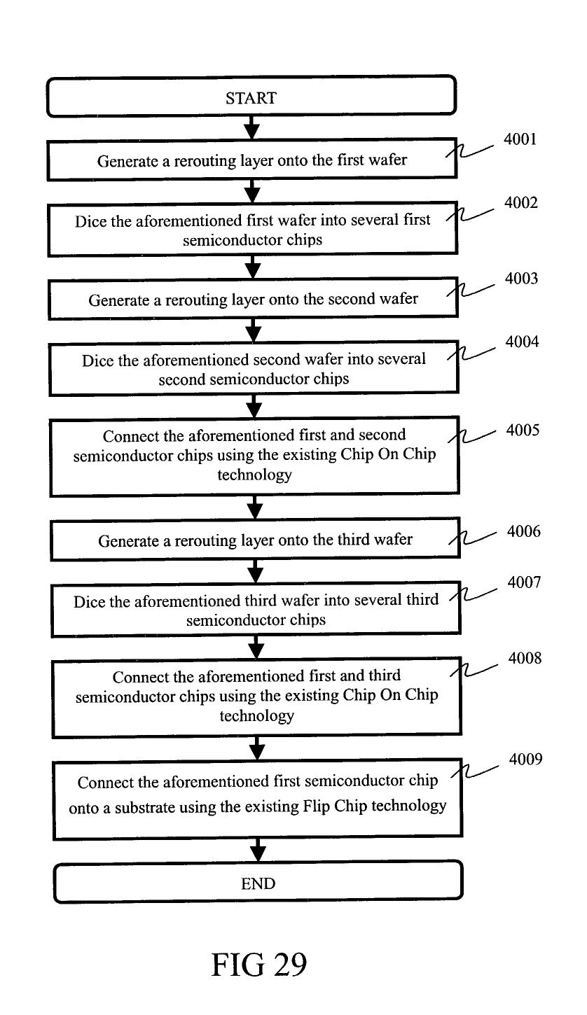

Manufacturing Method Embodiment XI (Please Refer to FIG. 29 for This Example and FIG. 20 for Related Structure.)

The manufacturing procedure for this invention is as follows:

1. Generate a rerouting layer onto the first wafer (Step 4001) using some existing technology.

2. Dice the aforementioned first wafer into several first semiconductor chips (Step 4002).

3. Generate a rerouting layer onto the second wafer (Step 4003) using some existing technology.

4. Dice the aforementioned second wafer into several second semiconductor chips (Step 4004).

5. Connect the aforementioned first and second semiconductor chips using the existing Chip On Chip technology (Step 4005).

6. Generate a rerouting layer onto the third wafer (Step 4006) using some existing technology.

7. Dice the aforementioned third wafer into several third semiconductor chips (Step 4007).

8. Connect the aforementioned first and third semiconductor chips using the existing Chip On Chip technology (Step 4008).

9. Connect the aforementioned first semiconductor chip onto a substrate using the existing Flip Chip technology (Step 4009).

Similarly, the manufacturing of the aforementioned wafers can be outsourced to companies of different manufacturing specialties with optimal production conditions for certain chips. To reduce thermal stress concentration due to thermal cycling that may cause cracking on the surface of flip-chip bonding, underfill encapsulant 501 is used to fill the gap between substrate 201 and all the semiconductor chips. Using the procedure detailed above, the best combination of CPU and ROM can be achieved with product application programs burned right in the ROM for an IC package like a Single Chip Microcomputer with a smaller form factor that can be produced at relatively low cost.

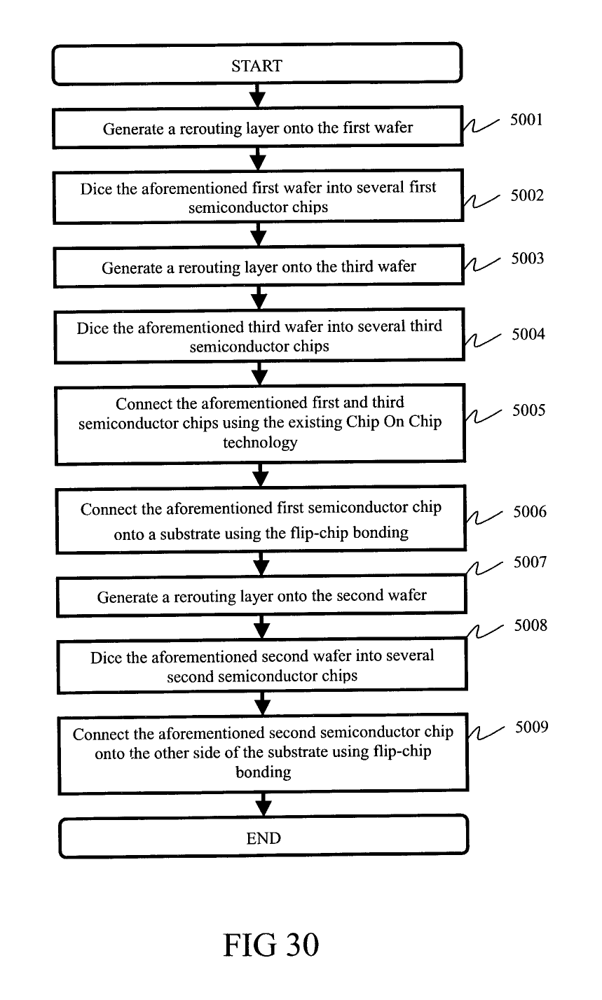

Manufacturing Method Embodiment XII (Please Refer to FIG. 30 for This Example and FIG. 19 for Related Structure.)

The manufacturing procedure for this invention is as follows:

1. Generate a rerouting layer onto the first wafer (Step 5001) using some existing technology.

2. Dice the aforementioned first wafer into several first semiconductor chips (Step 5002).

3. Generate a rerouting layer onto the third wafer (Step 5003) using some existing technology.

4. Dice the aforementioned third wafer into several third semiconductor chips (Step 5004).

5. Connect the aforementioned first and third semiconductor chips using the existing Chip On Chip technology (Step 5005).

6. Connect the aforementioned first semiconductor chip onto a substrate using the flip-chip bonding (Step 5006).

7. Generate a rerouting layer onto the second wafer (Step 5007) using some existing technology.

8. Dice the aforementioned second wafer into several second semiconductor chips (Step 5008).

9. Connect the aforementioned second semiconductor chip onto the other side of the substrate using flip-chip bonding (Step 5009).

Similarly, the manufacturing of the aforementioned wafers can be outsourced to companies of different manufacturing specialties with optimal production conditions for certain chips. To reduce thermal stress concentration due to thermal cycling that may cause cracking on the surface of flip-chip bonding, underfill encapsulant 501 is used to fill the gap between substrate 201 and all the semiconductor chips. Using the procedure detailed above, the best combination of CPU and ROM can be achieved with product application programs burned right in the ROM for an IC package like a Single Chip Microcomputer with a smaller form factor that can be produced at relatively low cost.

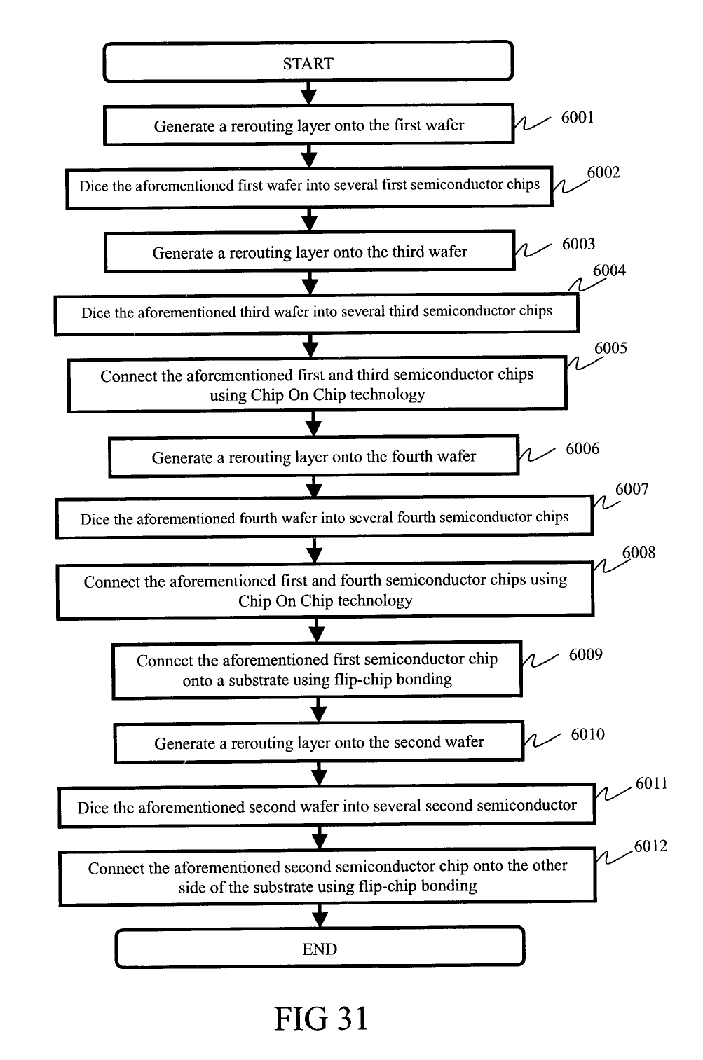

Manufacturing Method Embodiment XIII (Please Refer to FIG. 31 for This Example and FIG. 20 for Related Structure.)

The manufacturing procedure for this invention is as follows:

1. Generate a rerouting layer onto the first wafer (Step 6001) using some existing technology.

2. Dice the aforementioned first wafer into several first semiconductor chips (Step 6002).

3. Generate a rerouting layer onto the third wafer (Step 6003) using some existing technology.

4. Dice the aforementioned third wafer into several third semiconductor chips (Step 6004).

5. Connect the aforementioned first and third semiconductor chips using Chip On Chip technology (Step 6005).

6. Generate a rerouting layer onto the fourth wafer (Step 6006) using some existing technology.

7. Dice the aforementioned fourth wafer into several fourth semiconductor chips (Step 6007).

8. Connect the aforementioned first and fourth semiconductor chips using Chip On Chip technology (Step 6008).

9. Connect the aforementioned first semiconductor chip onto a substrate using flip-chip bonding (Step 6009).

10. Generate a rerouting layer onto the second wafer (Step 6010) using some existing technology.

11. Dice the aforementioned second wafer into several second semiconductor chips (Step 6011).

12. Connect the aforementioned second semiconductor chip onto the other side of the substrate using flip-chip bonding (Step 6012).

Similarly, the manufacturing of the aforementioned wafers can be outsourced to companies of different manufacturing specialties with optimal production conditions for certain chips. To reduce thermal stress concentration due to thermal cycling that may cause cracking on the surface of flip-chip bonding, underfill encapsulant 501 is used to fill the gap between substrate 201 and all the semiconductor chips. Using the procedure detailed above, the best combination of CPU and ROM can be achieved with product application programs burned right in the ROM for an IC package like a Single Chip Microcomputer with a smaller form factor that can be produced at relatively low cost.

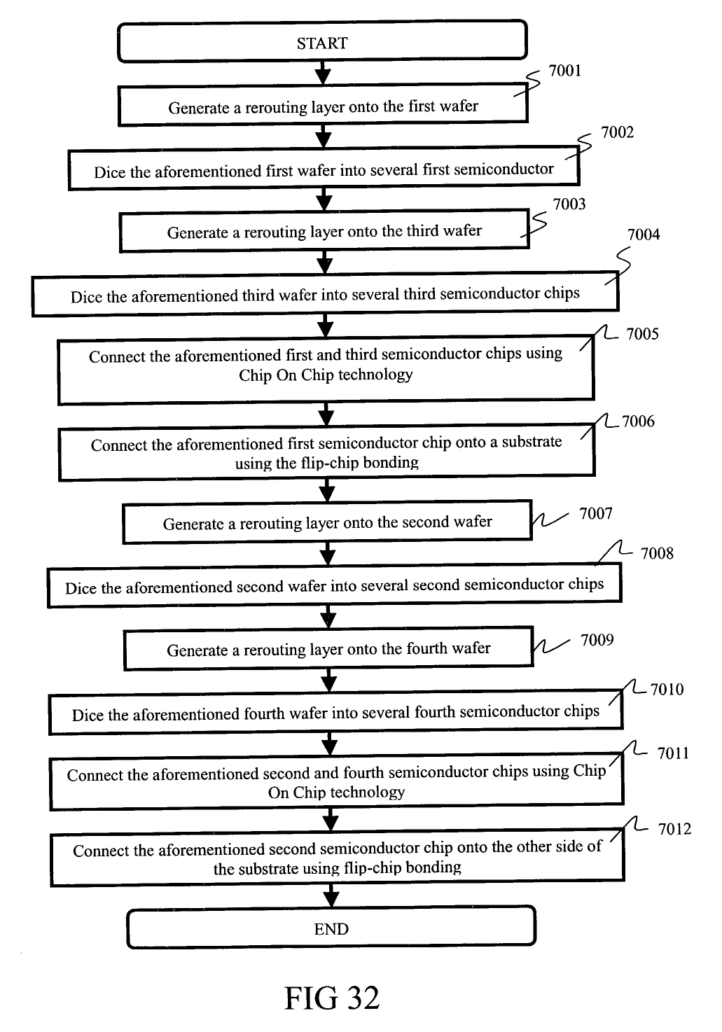

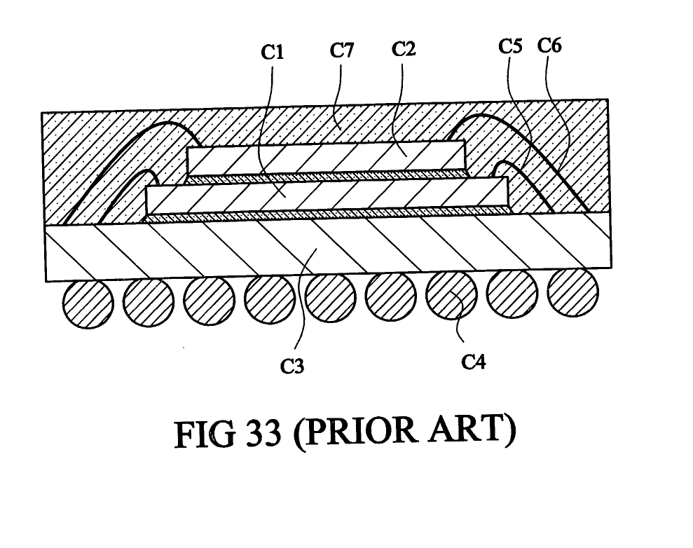

Manufacturing Method Embodiment XIV (Please Refer to FIG. 32 for This Example.)

The manufacturing procedure for this invention is as follows:

1. Generate a rerouting layer onto the first wafer (Step 7001) using some existing technology.

2. Dice the aforementioned first wafer into several first semiconductor chips (Step 7002).

3. Generate a rerouting layer onto the third wafer (Step 7003) using some existing technology.

4. Dice the aforementioned third wafer into several third semiconductor chips (Step 7004).

5. Connect the aforementioned first and third semiconductor chips using Chip On Chip technology (Step 7005).

6. Connect the aforementioned first semiconductor chip onto a substrate using the flip-chip bonding (Step 7006).

7. Generate a rerouting layer onto the second wafer (Step 7007) using some existing technology.

8. Dice the aforementioned second wafer into several second semiconductor chips (Step 7008).

9. Generate a rerouting layer onto the fourth wafer (Step 7009) using some existing technology.

10. Dice the aforementioned fourth wafer into several fourth semiconductor chips (Step 7010).

11. Connect the aforementioned second and fourth semiconductor chips using Chip On Chip technology (Step 7011).

12. Connect the aforementioned second semiconductor chip onto the other side of the substrate using flip-chip bonding (Step 7012).

Similarly, the manufacturing of the aforementioned wafers can be outsourced to companies of different manufacturing specialties with optimal production conditions for certain chips. To reduce thermal stress concentration due to thermal cycling that may cause cracking on the surface of flip-chip bonding, underfill encapsulant 501 is used to fill the gap between substrate 201 and all the semiconductor chips. Using the procedure detailed above, the best combination of CPU and ROM can be achieved with product application programs burned right in the ROM for an IC package like a Single Chip Microcomputer with a smaller form factor that can be produced at relatively low cost.

Furthermore, optoelectronic device 701 can be mounted to the top of the first semiconductor chip mentioned in all the previous examples. Referring to the structure shown in FIGS. 24 and 25, the surface of the first semiconductor chip 101 adopts an insulating Chip Coating Paste 502 for attaching optoelectronic device 701 and wire bonding is used to electrically connect optoelectronic device 701 to

Based on the manufacturing methods and IC packages of this invention, each semiconductor chip can be first manufactured separately under its corresponding optimal production process. The method of separately and independently manufacturing each semiconductor chip, substrate, and then assembling the semiconductor chips and substrates shortens the production time of an IC package. As for the structure of the IC packages of this invention, the wire among the semiconductor chips and between each semiconductor chip and the substrates are shortened to improve electrical performance. Furthermore, by merely rearranging the semiconductor chips, the total function of an IC package can be changed and extended to meet any new requirements with a short leadtime.

The aforementioned package structure examples have illustrated this invention in detail. However, the purpose of these examples is not to set limitations to this invention. The inventor claims the right to any variation or adaptation of IC package designs that is within the scope of this patent application. This is because it is easy for any one who is familiar with this invention to design or modify an IC package to achieve equivalent functionality.

I claim:

1. An IC package comprising:
a first semiconductor chip;
a second semiconductor chip, which directly connects to the first semiconductor chip by Chip On Chip (COC) bonding; and
a substrate onto which the first and/or second semiconductor chip is connected by Flip Chip (FC) bonding; wherein said substrate having an area for distributing an array of conductive terminals for connecting to a circuit outside the package by Ball Grid Array (BGA) bonding.

2. The IC package of claim 1, wherein the substrate having an opening or cavity for housing one of the first or second semiconductor chip.

3. The IC package of claim 2, wherein the first semiconductor chip having a metal rerouting layer for transmitting a signal or making a connection between the second semiconductor chip and the substrate.

4. The IC package of claim 2, wherein the second semiconductor chip having a metal rerouting layer for transmitting a signal or making a connection between the first semiconductor chip and the substrate.

5. An IC package comprising:
a first semiconductor chip;
a second semiconductor chip; and
a substrate having a first surface and second surface, wherein the first surface is connected to the first semiconductor and the second surface is connected to the second semiconductor by a Flip Chip (FC) bonding; and wherein one of the first surface or second surface of the substrate, having an area for distributing an array of conductive terminals for connecting to a circuits outside the package for connecting by Ball Grid Array (BGA) bonding.

6. The IC package of claim 5, wherein the substrate having a metal wire and through-hole for transmitting a signal or making a connection between the first and second semiconductor chips.

7. The IC package of claim 5, further comprising a third semiconductor chip which connected to the top of the first semiconductor chip by Chip On Chip (COC) bonding.

8. The IC package of claim 7, wherein the substrate having an opening or cavity for housing the third semiconductor chip.

9. The IC package of claim 7, further comprising a forth semiconductor chip which connected to the top of the second semiconductor chip by Chip On Chip (COC) bonding.

10. The IC package of claim 9, wherein the substrate having an opening or cavity for housing the third or fourth semiconductor chip.

11. An IC package comprising:
a first semiconductor chip;
a second semiconductor chip, which is connected directly to the first semiconductor chip by Chip On Chip (COC) bonding;
a substrate onto which the first or second semiconductor chip connects by Flip Chip (FC) bonding; wherein said substrate having an external conductive terminals; and
an interposer having a first side and a second side, wherein the first side is connected to the external terminals of the substrate, and wherein said second side having an area for distributing an array of conductive terminals for connecting to a circuit outside the package by Ball Grid Array (BGA) bonding.

12. The IC package of claim 11, wherein the substrate having an opening or cavity for housing one of the first or second semiconductor chip.

13. The IC package of claim 11, wherein the first semiconductor chip having a metal interconnects for transmitting a signal or making a connection between the second semiconductor chip and the substrate.

14. The IC package of claim 11, wherein the second semiconductor chip having a metal interconnects for transmitting a signal or making a connection between the first semiconductor chip and the substrate.

15. The IC package of claim 11, wherein the interposer having a metal wire and through-hole for transmitting a signal or making a connection between the substrate and a circuits outside the package.

16. The IC package of claim 15, wherein the interposer having a thickness at least bigger than the thickness of the first or second semiconductor chip.

17. The IC package of claim 15, the interposer is connected to an IC package of claim 11.

18. An IC package comprising:
a first semiconductor chip
a second semiconductor chip
a first semiconductor chip;
a second semiconductor chip;
a substrate having a first side and second side, wherein the first side is connected to the first semiconductor and the second side is connected to the second semiconductor by a Flip Chip (FC) bonding; and wherein one of the first side or second side of the substrate, having a external terminals; and
An interposer which connects to the external terminals of the substrate on one side, and wherein the interposer having another side for distributing an array of conductive terminals for connecting to a circuits outside the package for connecting by Ball Grid Array (BGA) bonding.

19. The IC package of claim 18, wherein the substrate having a rerouting layer and through-hole for directly transmitting a signals or make a connection between the first and second semiconductor chips.

20. The IC package of claim 18, further comprising a third semiconductor chip which connected to the top of the first semiconductor chip by Chip On Chip (COC) bonding.

21. The IC package of claim 20, wherein the substrate having an opening or cavity for housing the third semiconductor chip.

22. The IC package of claim 20, further comprising a fourth semiconductor chip which connected to the top of the second semiconductor chip by Chip On Chip (COC) bonding.

23. The IC package of claim 22, wherein the substrate having an opening or cavity for housing one of the third or fourth semiconductor chip.

24. The IC package of claim 18, wherein the interposer having a metal rerouting layer and through-hole for directly transmitting a signals or make a connection between the substrate and circuits outside the package.

25. The IC package of claim 24, the height of the interposer should be greater than the greater of the height of the first and second semiconductor chip.
wherein the interposer is thicker than the first or second semiconductor chip.

26. The IC package of claim 24, the interposer is connected to an IC package of claim 18.

27. An IC package includes at least the following:
a first semiconductor chip;
a second semiconductor chip, which directly connects to the first semiconductor chip by Chip On Chip (COC) bonding; and
a flexible circuit board onto which the first or second semiconductor chip is connected by Flip Chip (FC) bonding.

28. The IC package of claim 27, wherein the flexible circuit board having an opening or cavity for inserting one of the first or second semiconductor chip.

29. The IC package of claim 28, wherein the first semiconductor chip having a metal rerouting layer for transmitting a signal or making a connection between the second semiconductor chip and the flexible circuit board.

30. The IC package of claim 28, wherein the second semiconductor chip having a metal rerouting layer for transmitting a signal or making a connection between the first semiconductor chip and the flexible circuit board.

31. An IC package comprising:
a first semiconductor chip;
a second semiconductor chip; and
a flexible circuit board onto which the first and second semiconductor chips are connected to opposite sides by Flip Chip (FC) bonding.

32. The IC package of 31, wherein the flexible circuit board having a metal rerouting layer for directly transmitting a signal or making a connection between the first and second semiconductor chips.

33. The IC package of claim 31, further comprising a third semiconductor chip which connected to the top of the first semiconductor chip by Chip On Chip (COC) bonding.

34. The IC package of claim 33, wherein the flexible circuit board having an opening or cavity for inserting the third semiconductor chip.

35. The IC package of claim 33, further comprising a forth semiconductor chip which connected to the top of the second semiconductor chip by Chip On Chip (COC) bonding.

36. The IC package of claim 35, wherein the flexible circuit board having an opening or cavity for inserting the fourth semiconductor chip.

37. An IC package comprising:
a substrate having an surface for distributing an array of conductive terminals for connecting to a circuit outside the package by Ball Grid Array (BGA) bonding;
a first semiconductor chip which is connected to the substrate by Flip Chip (FC) bonding; and
An optoelectronic device which is directly electrically connected to the substrate.

38. The IC package of claim 37, the optoelectronic device is directly electrically connected to the substrate by wire-bonding.

39. The IC package of claim 37, the optoelectronic device is mounted on one side of the first semiconductor chip using an insulating Chip Coating Paste.

40. The IC package of claim 37, the substrate is a flexible circuit board such as a Tape Automated Bonding (TAB) substrate.

41. The IC package of claim 37, further comprising a second semiconductor chip connected to one side of the substrate by Flip Chip (FC) bonding.

42. The IC package of claim 37, further comprising a second semiconductor chip connected to the top of the first semiconductor chip by Flip Chip (FC) bonding.

43. The IC package of claim 42, wherein the substrate having an opening or cavity for housing the second semiconductor chip.

44. The IC package of claim 43, wherein the first semiconductor chip having a metal rerouting layer for transmitting a signal or making a connection between the second semiconductor chip and the substrate.

45. An IC package comprising:
a substrate having an surface for distributing an array of conductive terminals for connecting to a circuit outside the package by Ball Grid Array (BGA) bonding;
a first semiconductor chip which is connected to the substrate by Flip Chip (FC) bonding;
an optoelectronic device which is directly electrically connected to the substrate; and
a lens for collecting light and directs it to the surface of the optoelectronic device.

46. The IC package of claim 45, wherein the optoelectronic device directly connects to the substrate by wire-bonding.

47. The IC package of claim 45, wherein the optoelectronic device is mounted on one side of the first semiconductor chip using an insulating Chip Coating Paste.

48. The IC package of claim 45, wherein the substrate is a flexible circuit board such as a known Tape Automated Bonding (TAB) substrate.

49. The IC package of claim 45, wherein the optoelectronic device is a known light sensor or charge-coupled device.

50. The IC package of claim 45, wherein the lenses is fixed onto the substrate with a cap.

51. The IC package of claim 45, further comprising a second semiconductor chip connected to a side of the substrate by Flip Chip (FC) bonding.

52. The IC package of claim 51, wherein the second semiconductor chip connected to the top of the first semiconductor chip by Flip Chip (FC) bonding.

53. The IC package of claim 52, wherein the substrate having an opening or cavity for housing the second semiconductor chip.

54. The IC package of claim 53, wherein the first semiconductor chip having a metal rerouting layer for transmitting a signal or making a connection between the second semiconductor chip and the substrate.

55. A method for fabricating an IC package comprising at least the following steps:
a rerouting layers generating step, for generating a rerouting layers onto a first and second wafers which is separately fabricated by known method;
a first dicing step, for dicing said first wafer into a plurality of first semiconductor chips;
a second dicing step, for dicing said second wafer into a plurality of second semiconductor chips; and
a Flip Chip (FC) bonding step, for mounting said first and second semiconductor chips onto a substrate.

56. A method for fabricating an IC package comprising at least the following steps:
a rerouting layers generating step, for generating a rerouting layers onto a first, second, and third wafers which is separately fabricated by known method;
a first dicing step, for dicing said first wafer into a plurality of first semiconductor chips;
a second dicing step, for dicing said second wafer into a plurality of second semiconductor chips;
a third dicing step, for dicing said third wafer into a plurality of third semiconductor chips; and
a Flip Chip (FC) bonding step, for mounting said first semiconductor chip onto one side of the substrate and the second and third semiconductor chips onto the other side of the substrate.

57. A method for fabricating an IC package comprising at least the following steps:
a rerouting layers generating step, for generating a rerouting layers onto a first, second, and third wafers which is separately fabricated by known method;
a first dicing step, for dicing said first wafer into a plurality of first semiconductor chips;
a second dicing step, for dicing said second wafer into a plurality of second semiconductor chips;
a Chip On Chip (COC) bonding step, for mounting said first and second semiconductor chips together; and
a Flip Chip (FC) bonding step, for mounting said first semiconductor chip onto a substrate.

58. A method for fabricating an IC package comprising at least the following steps:
a rerouting layers generating step, for generating a rerouting layers onto a first, second, and third wafers which is separately fabricated by known method;
a first dicing step, for dicing said first wafer into a plurality of first semiconductor chips;
a second dicing step, for dicing said second wafer into a plurality of second semiconductor chips;
a third dicing step, for dicing said third wafer into a plurality of third semiconductor chips;
a Chip On Chip (COC) bonding step, for mounting said first, second, and third semiconductor chips together; and
a Flip Chip (FC) bonding step, for mounting one of said first, second, and third semiconductor chips onto a substrate.

59. A method for fabricating an IC package comprising at least the following steps:
a rerouting layers generating step, for generating a rerouting layers onto a first, second, and third wafers which is separately fabricated by known method;
a first dicing step, for dicing said first wafer into a plurality of first semiconductor chips;
a second dicing step, for dicing said second wafer into a plurality of second semiconductor chips;
a third dicing step, for dicing said third wafer into a plurality of third semiconductor chips;
a Chip On Chip (COC) bonding step, for mounting said first and third semiconductor chips together; and
a Flip Chip (FC) bonding step, for mounting one of the aforementioned first and third semiconductor chips onto one side of the substrate and the second semiconductor chip onto the other side.

60. A method for fabricating an IC package comprising at least the following steps:
a rerouting layers generating step, for generating a rerouting layers onto a first, second, third and fourth wafers which is separately fabricated by known method;
a first dicing step, for dicing said first wafer into a plurality of first semiconductor chips;
a second dicing step, for dicing said second wafer into a plurality of second semiconductor chips;
a third dicing step, for dicing said third wafer into a plurality of third semiconductor chips;
a fourth dicing step, for dicing said third wafer into a plurality of fourth semiconductor chips;
a Chip On Chip (COC) bonding step, for mounting said first and third semiconductor chips together and mounting the second and fourth semiconductor chips together; and
a Flip Chip (FC) bonding step, for mounting one of the aforementioned first and third semiconductor chips onto one side of the substrate and one of the second and fourth semiconductor chips onto the other side.
